(19) United States
(12) Patent Application Publication
(10) Pub. No.: US 2024/0231403 A1
(43) Pub. Date: Jul. 11, 2024

(54) ADAPTIVE CURRENT LIMIT CIRCUIT

(71) Applicant: Texas Instruments Incorporated, Dallas, TX (US)

(72) Inventors: Weibing Jing, Beijing (CN); Qi Yang, Beijing (CN); Liang Zhang, Beijing (CN)

(21) Appl. No.: 18/151,602

(22) Filed: Jan. 9, 2023

(51) Int. Cl. G05F 1/575; G05F 1/573; G05F 3/26; H02M 3/158

(52) U.S. Cl. CPC G05F 1/575; G05F 1/5735; G05F 3/262; H02M 3/1582

(57) ABSTRACT

A power supply circuit includes an amplifier and first and second transistors. The amplifier is configured to provide a drive potential at its output. The first transistor is coupled between a voltage supply terminal and an output terminal, and has a first control terminal coupled to the amplifier output, and is configured to receive at least a portion of the drive potential at the first control terminal. The second transistor is coupled between the first control terminal and the output terminal, and has a second control terminal coupled to the amplifier output. A threshold voltage of the first transistor is lower than a threshold voltage of the second transistor. The second transistor can operate to adaptively reduce the portion of the drive potential at the first control terminal, for example, by the second transistor turning on responsive to a voltage at the output terminal being lower than a voltage level.

### TECHNICAL FIELD

This description relates to regulated power supplies, and more particularly, to an adaptive current circuit.

### BACKGROUND

The direct current (DC) output voltage provided by a standard power supply to a load can vary due to any number of factors such as transient conditions, environmental conditions, and changing load conditions. In such cases, a voltage regulator can be coupled between the power supply and the load and used to provide a regulated DC output voltage to the load. In this manner, the output voltage of the voltage regulator remains unaffected by abrupt or otherwise transient changes in the input supply voltage and the load current. There are many types of DC-to-DC voltage regulators, including switching regulators and linear regulators.

The source follower power supply configuration is widely used in DC-to-DC voltage regulator design. For instance, a switching regulator (e.g., buck converter) may use a source follower to charge the boot capacitor of a bootstrap circuit, and a linear regulator (e.g., low dropout voltage regulator, or LDO voltage regulator) may use a source follower to provide the regulated output voltage. A number of non-trivial issues remain with such regulators.

### SUMMARY

One example includes a power supply circuit that includes an amplifier and first and second transistors. The amplifier has an amplifier output, and is configured to provide a drive potential at the amplifier output. The first transistor is coupled between a voltage supply terminal and an output terminal, and has a first control terminal coupled to the amplifier output. The first transistor is configured to receive at least a portion of the drive potential at the first control terminal. The second transistor is coupled between the first control terminal and the output terminal, and has a second control terminal coupled to the amplifier output. A threshold voltage of the first transistor is lower than a threshold voltage of the second transistor, and the second transistor is configured to adaptively reduce the portion of the drive potential at the first control terminal by the second transistor turning on responsive to a voltage at the output terminal being lower than a voltage level. In one such example configuration, the power supply circuit may be included within an integrated circuit package, and the output terminal is a pin or pad of the integrated circuit package. The output terminal may be, for instance, a boot pin (to which a boot capacitor is coupled) or an output voltage pin.

Another example is a power supply circuit that includes an amplifier along with first, second and third transistors. The amplifier has an amplifier output and a voltage reference input.

The first transistor is coupled between a voltage supply terminal and an output terminal, and has a first control terminal coupled to the amplifier output. The second transistor is coupled between the first transistor and the output terminal, and has a second control terminal coupled to the amplifier output. The third transistor is coupled between the second transistor and the output terminal, and has a third control terminal and a body terminal, wherein the third control terminal is coupled to the amplifier output, and the body terminal is coupled to a reference terminal. In one such example configuration, the power supply circuit may be included within an integrated circuit package, and the output terminal is a pin or pad of the integrated circuit package. The output terminal may be, for instance, a boot pin or an output voltage pin.

Another example is a power supply circuit that includes an amplifier and first and second transistors. The amplifier has an amplifier output and a voltage reference input. The first transistor is coupled between a voltage supply terminal and an output terminal, and has a first control terminal coupled to the amplifier output. The second transistor is coupled between the first control terminal and the output terminal, and has a second control terminal coupled to the amplifier output.

A threshold voltage of the first transistor is lower than a second threshold voltage of the second transistor. In one such example configuration, the power supply circuit may be included within an integrated circuit package, and the output terminal is a pin or pad of the integrated circuit package. The output terminal may be, for instance, a boot pin or an output voltage pin.

### BRIEF DESCRIPTION OF THE DRAWINGS

FIG. 1A illustrates a block diagram of a switching power supply configured with an adaptive current limit circuit, in an example.

FIG. 1B illustrates a block diagram of a low dropout (LDO) voltage regulator configured with an adaptive current limit circuit, in an example.

FIG. 2 illustrates a regulated power supply circuit that is susceptible to damage caused by a short-circuit condition on given output pin.

FIG. 3 illustrates a schematic diagram of a switching power supply configured with an adaptive current limit circuit, in an example.

FIG. 4 illustrates a schematic diagram of a switching power supply configured with an adaptive current limit circuit, in another example.

FIG. 5 illustrates a schematic diagram of a switching power supply configured with an adaptive current limit circuit, in another example.

FIG. 6 illustrates a schematic diagram of a switching power supply configured with an adaptive current limit circuit, in another example.

FIG. 7A illustrates a further detailed schematic diagram of a switching power supply configured with an adaptive current limit circuit, in another example.

FIG. 7B illustrates a further detailed schematic diagram of a switching power supply configured with an adaptive current limit circuit, in another example.

FIG. 8A illustrates a schematic diagram of an LDO voltage regulator configured with an adaptive current limit circuit, in an example.

FIG. 8B illustrates a schematic diagram of an LDO voltage regulator configured with an adaptive current limit circuit, in another example.

FIG. 9 illustrates a method for adaptively limiting current in a regulated power supply, in an example.

### DETAILED DESCRIPTION

Adaptive current limit techniques are described herein. While the techniques can be used in any number of applications, they are particularly useful for limiting the current through a source follower power supply that is coupled to a terminal susceptible to short-circuiting. The techniques are adaptive, in that they can be used to provide both the desired transient response (relatively high current) during normal operation and low power dissipation (relatively low current) during a short-circuit condition. In an example, a power supply circuit includes an amplifier and first and second transistors. The amplifier has an amplifier output, and is configured to provide a drive potential at the amplifier output. The first transistor is coupled between a voltage supply terminal and an output terminal, and has a first control terminal coupled to the amplifier output. The first transistor is configured to receive at least a portion of the drive potential at the first control terminal. In one such example, this first transistor is configured as a source follower power supply. The second transistor is coupled between the first control terminal and the output terminal, and has a second control terminal coupled to the amplifier output. A threshold voltage of the first transistor is lower than a threshold voltage of the second transistor. In operation, the second transistor is configured to adaptively reduce the portion of the drive potential at the first control terminal, for example, by the second transistor turning on responsive to a voltage at the output terminal being lower than a voltage level (e.g., such as a voltage indicative of a short-circuit on the output terminal). The output terminal may be, for example, a pin or pad of an integrated circuit package, such as a pin to which a boot capacitor may be coupled (such as in a switching power supply) or an output voltage pin (such as in an LDO voltage regulator).

### General Overview

As described above, a number of non-trivial issues remain with DC-to-DC voltage regulators that employ a source follower power supply configuration. For example, in a switching regulator that uses a source follower to charge the boot capacitor of a bootstrap circuit, there may be very high power dissipation on the charge path if the boot pin is inadvertently shorted to ground, which may damage the source follower. In more detail, assume the switching regulator has a 12 volt input voltage and a 150 milliamp current, and the source follower is implemented with an n-channel field effect transistor (NFET). In such a case, if the boot pin is shorted to ground, about 1.8 watts of power is discharged on the charge path and across the NFET. Depending on its size, the NFET can easily be damaged by such relatively high power dissipation. One possible solution to this problem is to use a constant current source to limit the available current. For instance, a constant limit of 10 milliamps could be used to limit the power dissipation to about 0.12 watts, given a 12 volt input voltage. However, such a current limit would also limit the transient response current needed to charge the boot capacitor. A similar problem may arise in the context of an LDO regulator, where the pass element (passFET) can be damaged if the output voltage pin is inadvertently shorted to ground.

Thus, current limit circuitry is described herein to adaptively limit current through a power supply (e.g., a source follower power supply) coupled to an output pin or other terminal. Unlike a constant current source, the techniques can be used to provide both the desired transient response (relatively high current) during normal or first mode of operation and low power dissipation (relatively low current) during a short-circuit condition or second mode of operation. The techniques can be implemented in any number of power supply topologies.

### Circuit Architecture

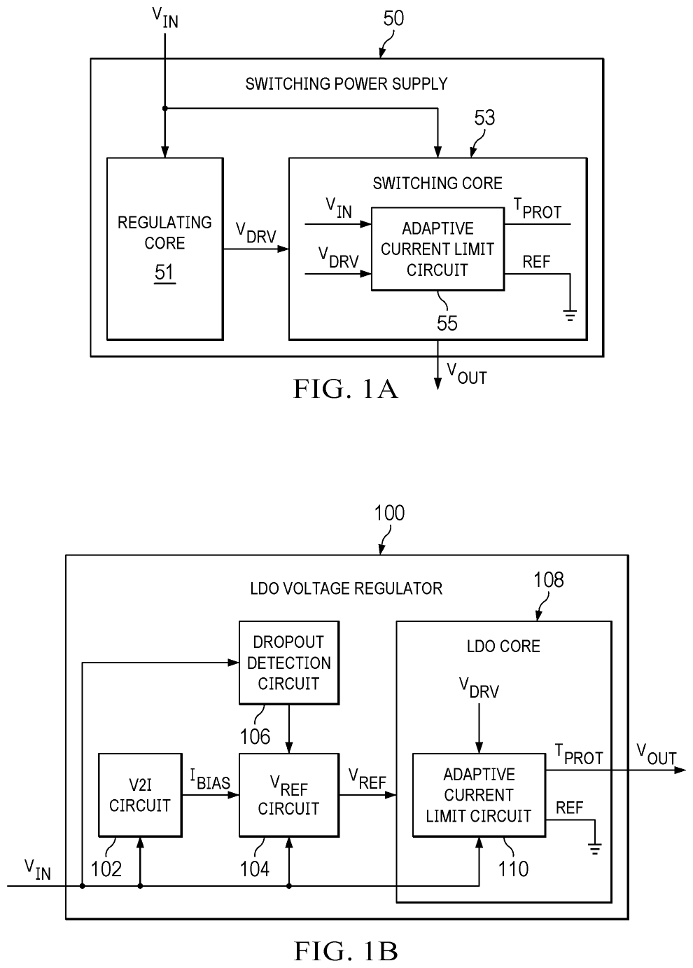

FIG. 1A illustrates a block diagram of a switching power supply 50 configured with an adaptive current limit circuit 55, in an example. As shown, the switching power supply 50 generally includes a regulating core 51 and a switching core 53. The adaptive current limit circuit 55 is implemented within the switching core 53. The switching power supply 50 receives a given input voltage (V_{IN}) at its input voltage terminal, and provides a regulated output voltage (V_{OUT}) at its output voltage terminal. The values or ranges of V_{IN} and V_{OUT} can vary from one embodiment to the next but in some examples are both in the range of 3.3 volts to 35 volts (e.g., V_{IN} equals 5 volts or 12 volts, and V equals 5 volts or 8 volts).

The regulating core 51 is configured to generate a drive signal (V_{DRV}) based on a given input voltage (V_{IN} ) and a given reference voltage. In this example case, the reference voltage is generated internal to the regulating core 51, but in other cases the reference voltage may be generated external to the regulating core 51. The switching core 53 receives the drive signal V_{DRV} as well as the input voltage V_{IN}, and is configured to generate the regulated output voltage (V_{OUT}). Each of the regulating core 51 and the switching core 53 can be implemented with any suitable configurations, except that the switching core 53 is further configured with the adaptive current limit circuit 55. In some examples, the regulating core 51 and the switching core 53 are configured to implement a buck converter, a boost converter, a buck-boost converter, or a flyback converter. More generally, the regulating core 51 and the switching core 53 can be any power supply circuitry that includes a terminal (e.g., pin, pad, internal node, or external node) to which power is sourced, and that terminal is susceptible to short-circuit conditions or some other condition that may cause excess current flow to that terminal.

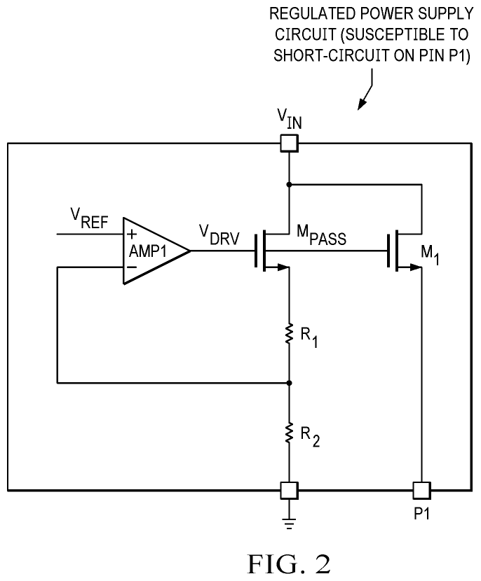

As shown, adaptive current limit circuit 55 is coupled to the V_{IN} terminal, a reference or ground terminal (REF), and the output of the regulating core 51, such that it receives the drive signal V_{DRV} as input. The adaptive current limit circuit 55 is further coupled to a terminal to be protected (T_{PROT}) in the event of a short-circuit condition at that terminal. In an example, the terminal T_{PROT} is coupled to the output of a source follower power supply implemented within the switching power supply 50, such as in a bootstrap circuit. The terminal T_{PROT} may be, for example, a node within switching power supply 50 or a pin or pad of an integrated circuit package in which switching power supply 50 resides. More generally, the terminal T_{PROT} may be any conductor to which power is sourced via a source follower power supply, or any other power supply that might be damaged due to a short-circuit or other high-current condition. In operation, adaptive current limit circuit 55 is configured to limit current flowing to the terminal T_{PROT} during a short-circuit or high-current condition at that terminal. Further details of adaptive current limit circuit 55 are described below with reference to FIGS. 2-7B and 9.

FIG. 1B illustrates a block diagram of a low dropout (LDO) voltage regulator 100 configured with an adaptive current limit circuit 110, in an example. As shown, the LDO voltage regulator 100 includes a voltage-to-current converter (V2I) circuit 102, a reference voltage (V_{REF}) circuit 104, a dropout detection circuit 106, and an LDO core 108. The adaptive current limit circuit 110 is implemented within the LDO core 108. The LDO voltage regulator 100 receives a given input voltage (V_{IN}) at its input voltage terminal, and provides a regulated output voltage (V_{OUT}) at its output voltage terminal. The values or ranges of V_{IN} and V_{OUT} can vary from one embodiment to the next but in some examples are both in the range of 3.3 volts to 35 volts (e.g., V_{IN} equals 5 volts or 12 volts, and V_{OUT} equals 5 volts or 8 volts).

The V2I circuit 102 is configured to provide a stable bias current (I_{BIAS}) to the V_{REF} 104. In one example, the V2I circuit 102 is implemented with a voltage-to-current converter circuit that includes bandgap voltage reference (BGVR), an operational amplifier, a FET, and a resistor. The BGVR is configured to provide a stable voltage reference to the input of amplifier and can be implemented with any number of standard or proprietary bandgap voltage reference circuit topologies, such as Brokaw, Widlar, and switched capacitor topologies. The amplifier can have a voltage follower configuration, with its inverting input tied to its output, and receives the output voltage of the BGVR at its non-inverting input. The output of the amplifier drives the gate of the FET. The resistor connects the FET source to ground, and the current through that resistor flows from the source to drain of the FET, thereby providing the bias current I_{BIAS} to the V_{REF} circuit 104, to help generate the reference voltage V_{REF}. More generally, V2I circuit 102 can be any number of voltage-to-current converter configurations.

The V_{REF} circuit 104 is configured to generate a reference voltage V_{REF} for the LDO core 108, based on the bias current I_{BIAS} from V2I circuit 102. In an example, the V_{REF} circuit 104 includes an amplifier and a transistor (such as a passFET or other switching element). The transistor is gated or otherwise controlled by an output signal of the amplifier. The amplifier is configured with first and second input resistances on its inverting and non-inverting inputs, respectively, which in conjunction with the bias current I_{BIAS} effectively determine the reference current. The reference current generated by the amplifier is passed through the transistor and a reference resistor (which may be external to the V_{REF} circuit 104), which in turn generates the reference voltage V that is provided to LDO core 108. More generally, V_{REF} circuit 104 can be implemented with any reference voltage generator circuit configurations.

The dropout detection circuit 106 senses a dropout condition and is configured to cause a higher reference current (sometimes called fast soft-start current, IF_{SS}) in V_{REF} circuit 104, so as to reduce the start-up time with a higher ramp rate on a reference capacitor coupled in parallel with a reference resistor, external or internal to V_{REF} circuit 104. Also, the dropout detection circuit 106 is configured to limit the overshoot on the reference voltage V_{REF} while the regulator is coming out of dropout, by disconnecting or otherwise disabling the fast soft-start current IFss responsive to the regulator output voltage V_{OUT} reaching a given voltage threshold, such as 90% of the target output voltage. In an example, dropout detection circuit 106 includes a comparator that outputs a logic low (or other dropout indicator signal) whenever the output voltage V_{OUT} falls out of regulation by more than a given threshold (e.g., ≥5%). The dropout indicator signal can be used to switch the fast soft-start current in and out as needed (e.g., by controlling the value of one of the input resistances on the input of the amplifier of V_{REF} circuit 104). More generally, dropout detection circuit 106 can be implemented with any configuration capable of adjusting the reference current provided by V_{REF} circuit 104 during dropout.

The LDO core 108 is configured to provide a regulated voltage output V_{OUT} based on the input supply voltage V_{IN} and the reference voltage V_{REF} provided by the V_{REF} circuit 104. In an example, the LDO core 108 includes a switching element (also called a pass element) such as a passFET coupled between the input voltage terminal V_{IN} and the output voltage terminal V_{OUT} in a source follower configuration, and an amplifier having a unity gain configuration for gating the switching element, via a drive signal V_{DRV}. More generally, LDO core 108 can be implemented with any LDO core configurations capable of generating a regulated output voltage based on an input supply voltage V_{IN} and a reference voltage V_{REF} provided by a reference voltage generation circuit, except that LDO core 108 is further configured with the adaptive current limit circuit 110.

Thus, each of the V2I circuit 102, V_{REF} circuit 104, dropout detection circuit 106, and LDO core 108 can be implemented with any suitable configurations, except that the LDO core 108 is further configured with the adaptive current limit circuit 110. More generally, LDO voltage regulator 100 can be any low dropout voltage circuitry that includes a terminal (e.g., pin, pad, internal node, or external node) to which power is sourced via a source follower power supply, or any other power supply that might be damaged due to a short-circuit or other high-current condition.

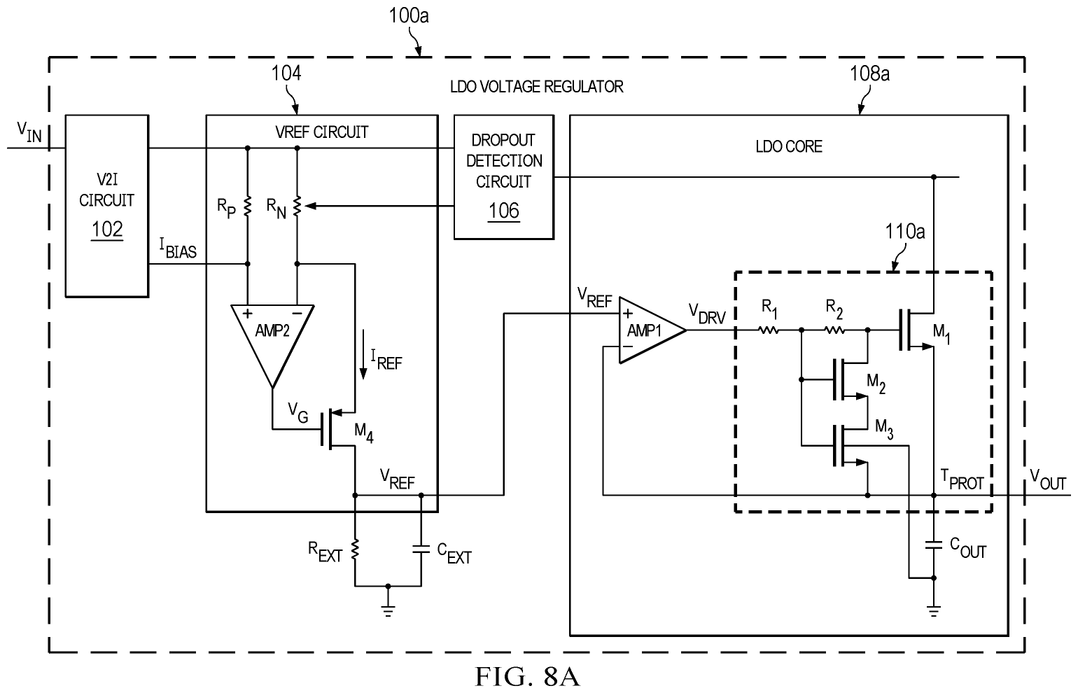

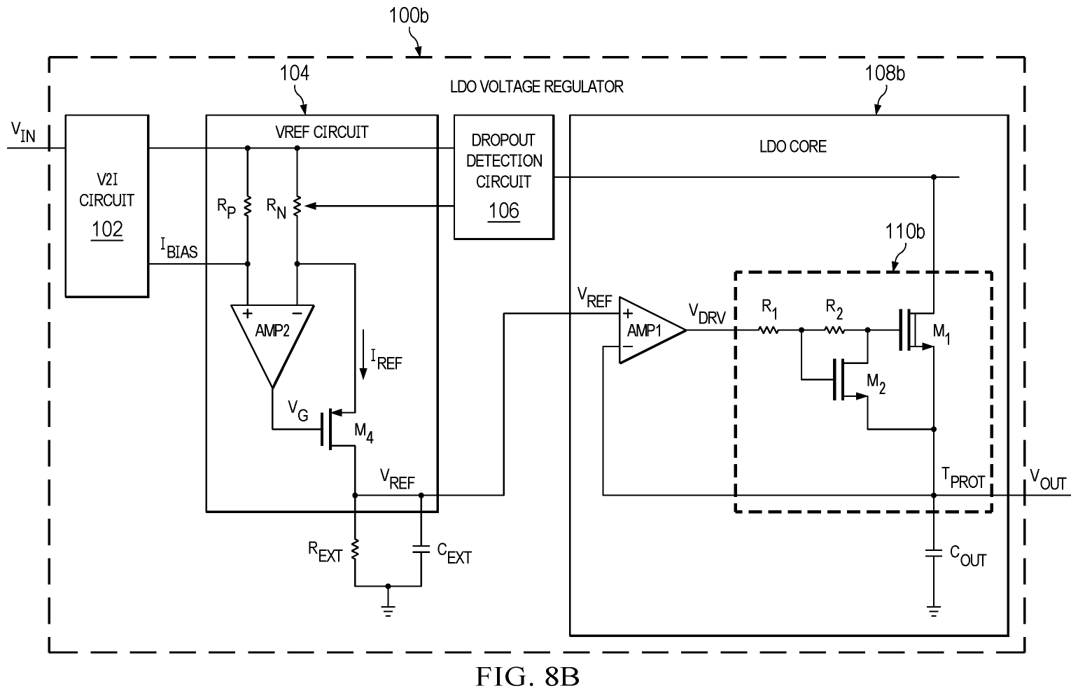

As shown, adaptive current limit circuit 110 is coupled to the V_{IN} terminal, a reference or ground terminal (REF), and the output of V_{REF} circuit 104, such that it receives the reference voltage V_{REF} as input. As described above, the LDO core 108 uses the reference voltage V_{REF} to generate a drive signal V_{DRV}, which current limit circuit 110 also receives as input. The adaptive current limit circuit 110 is further coupled to a terminal to be protected (T_{PROT}) in the event of a short-circuit condition at that terminal. The terminal T_{PROT} is coupled to the output of a source follower power supply implemented within LDO voltage regulator 100, such as a passFET in the LDO core 108. The terminal T_{PROT} may be, for example, a node within LDO voltage regulator 100 or a pin or pad of an integrated circuit package in which LDO voltage regulator 100 resides. In this example, terminal T_{PROT} is the output voltage V_{OUT} terminal. In operation, adaptive current limit circuit 110 is configured to limit current flowing to the terminal T_{PROT} (also the V_{OUT} terminal) during a short-circuit or other high-current condition at that terminal. Further details of adaptive current limit circuit 110 are described below with reference to FIGS. 8A-B and 9.

FIG. 2 illustrates a regulated power supply circuit that is susceptible to damage caused by a short-circuit condition on a given terminal. As shown, the circuit includes an operational amplifier (AMP1), a first n-channel FET (M₁), a second n-channel FET (M_{PASS}), and a voltage divider network (R₁ and R₂). The output voltage (V_{DRV}) of amplifier AMP₁ is applied to the gates of FETs M₁ and M_{PASS}. In operation, FET M_{PASS} is configured to pass current from the V_{IN} terminal to the voltage divider network, responsive to V_{DRV} at the M_{PASS} gate. The voltage divider network samples the voltage at the M_{PASS} source and provides that sample (V_{IN}*R₁/[R₁+R₂] to the inverting input of AMP₁. Because the M_{PASS} source voltage follows the output voltage of amplifier AMP1, such a configuration is sometimes referred to as a voltage follower. Also, FET M₁ is configured as a source follower power supply, so as to source power from the input voltage terminal V_{IN} to terminal P1, responsive to the output voltage V_{DRV} of amplifier AMP1. Unfortunately, if terminal P1 is inadvertently shorted to ground, then most of voltage V_{IN} will drop across FET M₁, thereby possibly damaging M₁.

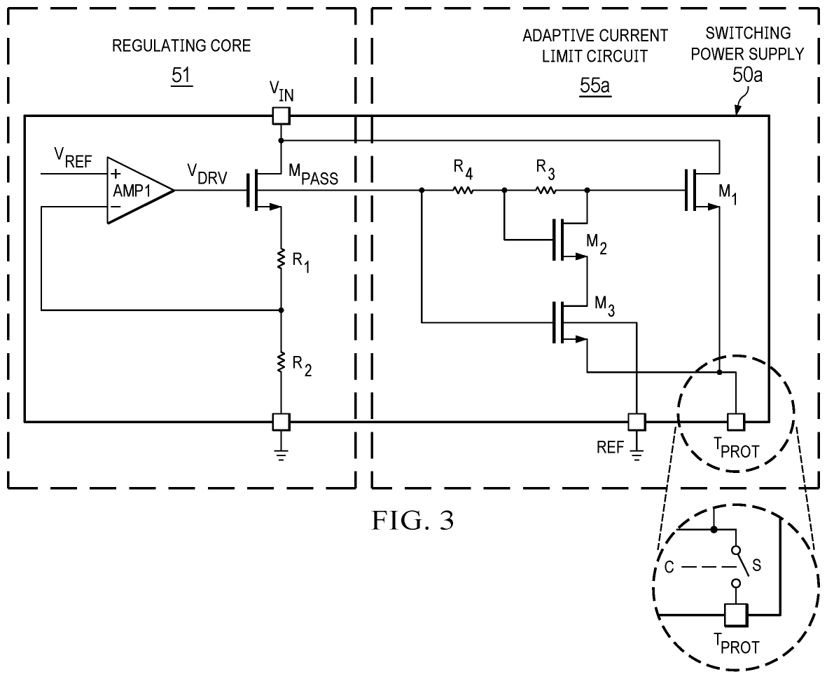

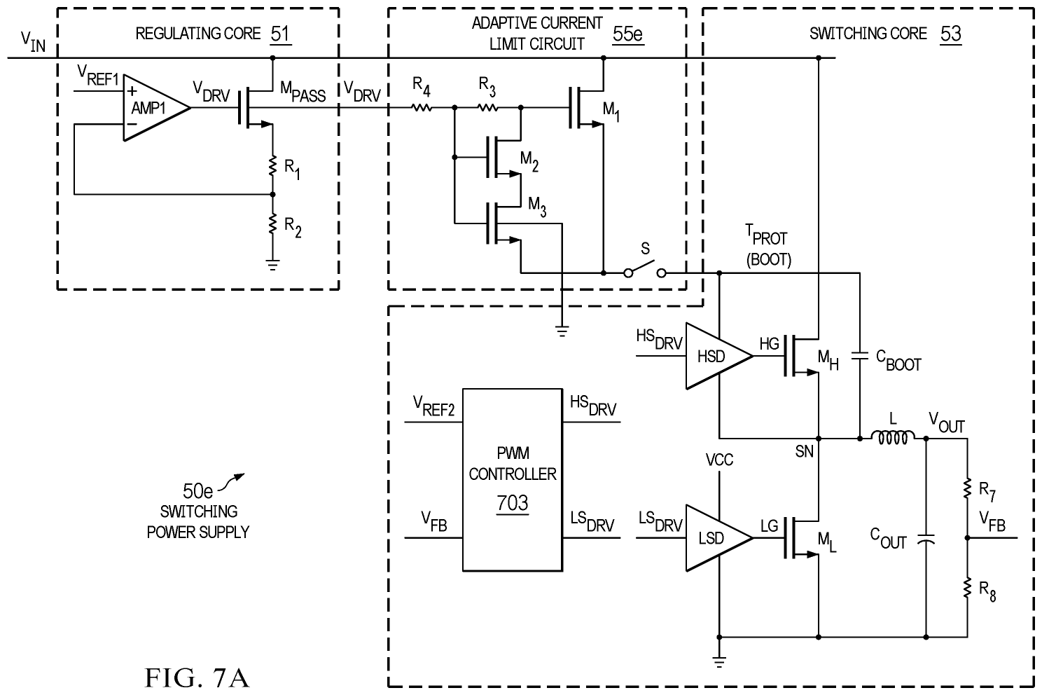

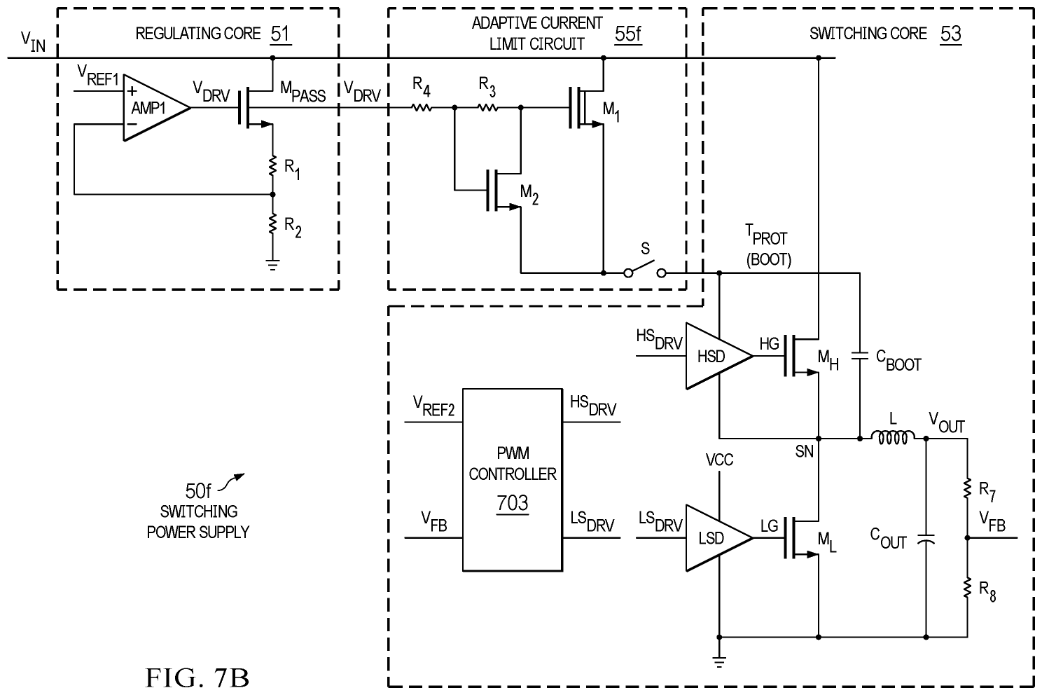

FIG. 3 illustrates a schematic diagram of a switching power supply 50a configured with an adaptive current limit circuit, in an example. As shown, switching power supply 50a generally includes a regulating core 51 and an adaptive current limit circuit 55a. Other portions of switching power supply 50a, such as the switching core, are not shown in FIG. 3, but are shown in FIGS. 7A-B. The regulating core 51 is configured as a voltage follower in a similar fashion to that shown in FIG. 2, and the above relevant description is equally applicable here.

The adaptive current limit circuit 55a of this example also includes n-channel FET M₁, which is configured as a source follower power supply, so as to source power from the input voltage terminal V_{IN} to terminal T_{PROT}, responsive to the output voltage V_{DRV} of amplifier AMP1. However, unlike the circuit of FIG. 2, the percentage or proportion of the output voltage V_{DRV} of amplifier AMP1 that is applied to the gate of FET M₁ can be varied based on the voltage level at terminal T_{PROT}. For instance, in this example, the current limit circuit 55a further includes resistors R₃ and R₄ operatively coupled to n-channel FETs M₂ and FET M₃, which are connected in a serial fashion between the gate of FET M₁ and terminal T_{PROT}. In more detail, resistors R₃ and R₄ are connected in series with one another between the AMP1 output and the M₁ gate, and can be used to fine tune the current flowing through M₁. The M₂ drain is connected to the M₁ gate, and resistor R₃ is connected between the gate and drain of M₂. The M₂ drain is connected to the M₂ source, and resistor R₄ is connected between the gates of M₂ and M₃. The M₃ source is connected to terminal T_{PROT}, and the M₃ body (or back-gate) is connected to a reference (REF) terminal (which in this case is connected to ground).

As shown, FETs M₁ and M₂ are arranged in a current mirror configuration and may be a matched pair (e.g., 1:1 ratio, with respect to transistor width and length) and have a similar voltage threshold (V_{TH}, sometimes called V_{GS}), although they need not be so matched. With its back-gate connected to the REF terminal, the threshold voltage V_{TH} of FET M₃ is larger than the V_{TH} of M₁.

In one example, for instance, R₃ and R₄ are each in the range of 10 KOhms to 200 KOhms (e.g., R₃ is in the range of about 10 KOhms to 100 KOhms; R₄ is in the range of about 100 KOhms to 200 KOhms), the threshold voltage V_{TH} of FET M₃ is in the range of 2 to 5 volts, and the V_{TH} of each of M₁ and M₂ is in the range of 0.6 to 1 volt. The source-to-drain on-resistance (R_{SD_ON}) of M₃ decreases proportionally with decreasing voltage at terminal T_{PROT}. In this manner, FET M₃ acts like a variable resistor and is configured to adaptively reduce the portion of the drive potential V_{DPV} applied at the M₁ gate, by M₃ turning on responsive to a voltage at the terminal T_{PROT} being lower than it should be (lower than a voltage level). The lower the voltage at terminal T_{PROT}, the lower the R_{SD_ON} of M₃ (the more M₃ turns on). The lower the R_{SD_ON} of M₃, the lower the portion of V_{DRV} applied to the M₁ gate.

For example, assume that terminal T_{PROT} is a boot capacitor terminal for a boot strap circuit of switching power supply 50a, and the voltage at terminal T_{PROT} is V_{BOOT} (e.g., about 5 volts) under normal conditions. Further assume V_{DRV} is around 5 to 6 volts, and that V_{TH} of M₃ is about 2 to 5 volts. So, in a normal operation mode, V_{DRV}−V_{BOOT} is less than V_{TH} of M₃ (e.g., 6 volts−5 volts=1 volt, which is less than 2 volts) and M₃ is off or otherwise barely conducting and is thus effectively an open circuit (e.g., R_{SD_ON} of M₃≥1 MOhm to infinite, or otherwise very high resistance). As such, no current is conducted by M₂, and the M₁ gate receives about 100% of V_{DRV}.

However, responsive to V_{DRV}−V_{BOOT} meeting or exceeding V_{TH} of M₃, normal operation mode ceases and M₂ and M₃ begin to conduct and the R_{SD_ON} of M₃ is set proportional to V_{DRV}−V_{BOOT}. So, as the value of V_{DRV}−V_{BOOT} further increases past V_{TH} of M₃, the more M₃ turns on (the current conducted through M₂ and M₃ increases with increasing values of V_{DRV}−V_{BOOT}). If terminal T_{PROT} is shorted to ground (presumably by accident), then V_{DRV}−V_{BOOT} is the maximum amount it can be and R_{SD_ON} of M₁ is the lowest it can be (e.g., 1 Ohm or otherwise very small relative to the impedance at the M₁ gate). With M₂ and M₃ conducting, a variable voltage divider is formed which allows the amount of V_{DRV} applied to the M₁ gate to be varied proportionally, relative to the voltage at terminal T_{PROT}. For instance, with terminal T_{PROT} shorted to ground, current sourced from the V_{DRV} potential seeks the lower resistant path through M₂ and M₃ (relative to the high impedance path to the M₁ gate), and the M₁ gate thus receives about 0% or an otherwise relatively small amount of V_{DRV}. For non-zero (non-short) voltage values at terminal T_{PROT}, the M₁ gate may receive a proportional amount of V_{DRV} (some value between about 0 volts and the full V_{DRV} potential). Thus, an adaptive limit on V_{IN} supply current through M₁ is provided.

As further shown in FIG. 3 in the dashed circle, some examples of switching power supply 50a may include a switch S coupled between the terminal T_{PROT} and the sources of M₁ and M₃. The switch may be controlled by control signal C. Control signal C may be activated, for example, when desired to disconnect terminal T_{PROT} from an active power source, such as when connecting a desired boot capacitor or some other situation (e.g., probing the value of a connected boot capacitor). Such a switching circuit may be further helpful to reduce over-current conditions at terminal T_{PROT} during in-field testing or assembly operations.

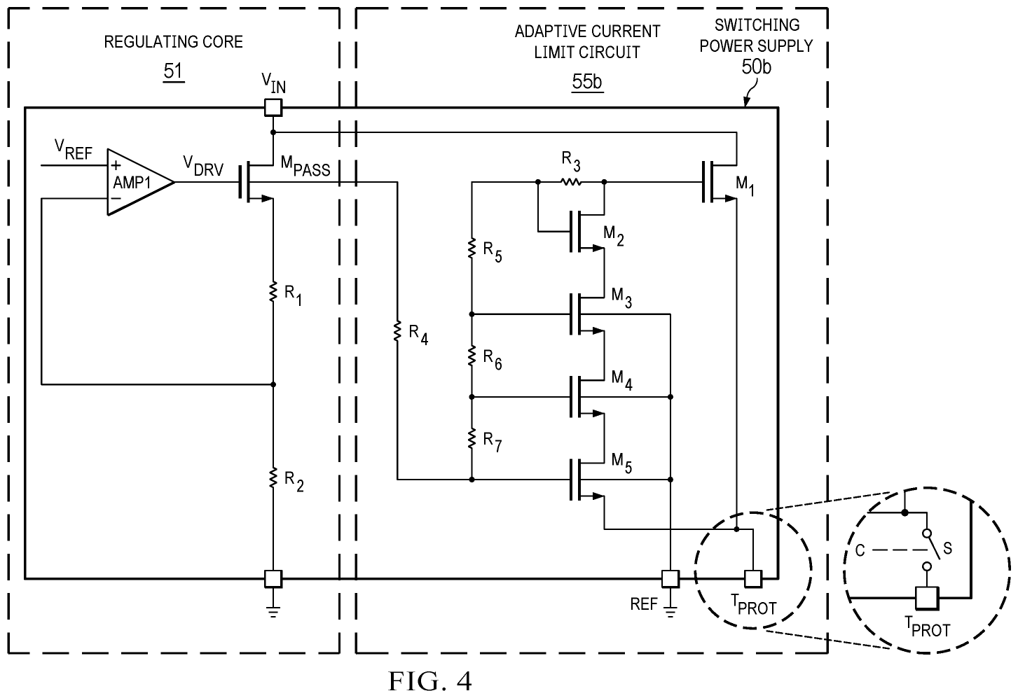

FIG. 4 illustrates a schematic diagram of a switching power supply 50b configured with an adaptive current limit circuit, in another example. As shown, switching power supply 50b generally includes a regulating core 51 and an adaptive current limit circuit 55b. Other portions of switching power supply 50b, such as the switching core, are not shown in FIG. 4, but are shown in FIGS. 7A-B. The regulating core 51 is configured as a voltage follower in a similar fashion to that shown in FIG. 2, and the above relevant description is equally applicable here.

The adaptive current limit circuit 55b of this example is similar to the adaptive current limit circuit 55a of FIG. 3, except that circuit 55b includes three serially-connected n-channel FETs M₃, M₄ and M₅ in place of FET n-channel M₃, and four serially-connected resistors R₄, R₅, R₆ and R₇ in place of resistor RR₄. The above relevant description with respect to FIG. 3 is equally applicable here. In a fashion similar to circuit 55a, the adaptive current limit circuit 55b operates such that the percentage or proportion of the output voltage V_{DRV} of amplifier AMP1 that is applied to the gate of FET M₁ can be varied based on the voltage level at terminal T_{PROT}.

For instance, in this example, the current limit circuit 55b further includes resistor R₄, R₅, R₆ and R₇ operatively coupled to n-channel FETs M₂ through M₅, which are connected in a serial fashion between the gate of FET M₁ and terminal T_{PROT}. In more detail, resistors R₃, R₄, R₅, R₆ and R₇ are connected in series with one another between the AMP1 output and the M₁ gate, and can be used to fine tune the current flowing through M₁. The M₂ drain is connected to the M₁ gate, and R₃ is connected between the gate and drain of M₂. The M₃ drain is connected to the M₂ source, and R₅ is connected between the gates of M₂ and M₃. The M₄ drain is connected to the M₃ source, and R₆ is connected between the gates of M₃ and M₄. The M₅ drain is connected to the M₄ source, and R₇ is connected between the gates of M₄ and M₅. The M₅ source is connected to terminal T_{PROT}, and the body (or back-gate) of each of M₃, M₄ and M₅ is connected to a reference (REF) terminal (which in this case is connected to ground). R₄ is connected between the AMP1 output and the M₅ gate.

As described above with reference to FIG. 3, FETs M₁ and M₂ are arranged in a current mirror configuration and may be a matched pair (e.g., 1:1 ratio, with respect to transistor width and length) and have a similar voltage threshold (V_{TH}, sometimes called V_{GS}), although they need not be so matched. With their back-gates connected to the REF terminal, the threshold voltages V_{TH} of each of FET M₃, M₄ and M₅ are larger than the V_{TH} of M₁. In one example, for instance, R₃, R₄, R₅, R₆ and R₇ are each in the range of 10 KOhms to 200 KOhms (e.g., each of R₃, R₅, R₆ and R₇ is in the range of about 10 KOhms to 100 KOhms; R₄ is in the range of about 100 KOhms to 200 KOhms), the threshold voltage V_{TH} of each of FETs M₃, M₄ and M₅ is in the range of 2 to 5 volts, and the V_{TH} of each of M₃, M₄ and M₅ in the range of 0.6 to 1 volt. The source-to-drain on-resistance (R_{SD_ON}) of each of M₃, M₄ and M₅ decreases proportionally with decreasing voltage at terminal T_{PROT}. In this manner, FETs M₃, M₄ and M₅ each acts like a variable resistor and together they are configured to adaptively reduce the portion of the drive potential V_{DRV} applied at the M₁ gate, in a similar fashion as described above with reference to FET M₃ of FIG. 3.

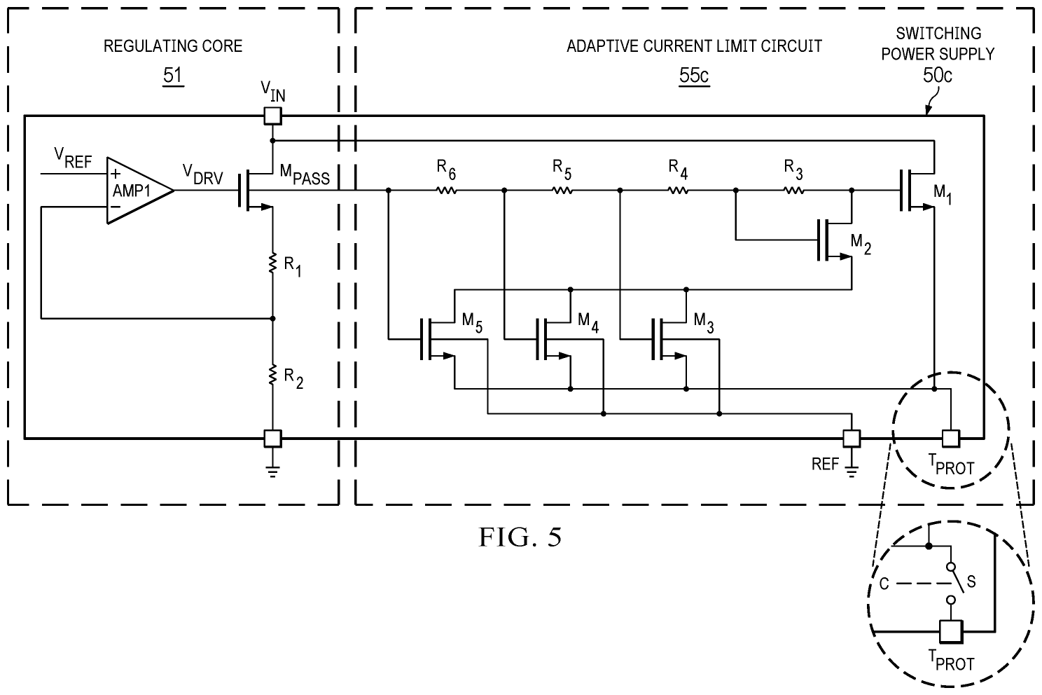

FIG. 5 illustrates a schematic diagram of a switching power supply 50c configured with an adaptive current limit circuit, in another example. As shown, switching power supply 50b generally includes a regulating core 51 and an adaptive current limit circuit 55c. Other portions of switching power supply 50c, such as the switching core, are not shown in FIG. 5, but are shown in FIGS. 7A-B. The regulating core 51 is configured as a voltage follower in a similar fashion to that shown in FIG. 2, and the above relevant description is equally applicable here.

The adaptive current limit circuit 55c of this example is similar to the adaptive current limit circuit 55a of FIG. 3, except that circuit 55c includes three parallel-connected n-channel FETs M₃, M₄ and M₅ in place of FET n-channel M₃, and three serially-connected resistors R₄, R₅ and R₆ in place of resistor R₄. The above relevant description with respect to FIG. 3 is equally applicable here. In a fashion similar to circuit 55a, the adaptive current limit circuit 55c operates such that the percentage or proportion of the output voltage V_{DRV} of amplifier AMP1 that is applied to the gate of FET M₁ can be varied based on the voltage level at terminal T_{PROT}.

For instance, in this example, the current limit circuit 55c further includes resistors R₃ through R₆ operatively coupled to n-channel FETs M₂ through M₅. M₂ is connected in a serial fashion with the parallel combination of M₃ through M₆ between the gate of FET M₁ and terminal T_{PROT}. In more detail, resistors R₃, R₄, R₅ and R₆ are connected in series with one another between the AMP1 output and the M₁ gate, and can be used to fine tune the current flowing through M₁. The M₂ drain is connected to the M₁ gate, and resistor R₄ is connected between the gate and drain of M₂. The M₃ drain is connected to the M₂ source, and resistor R₄ is connected between the gates of M₂ and M₃. The M₄ drain is connected to the M₃ drain, and resistor R₅ is connected between the gates of M₃ and M₄. The M₅ drain is connected to the M₄ drain, and resistor R₆ is connected between the gates of M₄ and M₅. The source of each of the M₃, M₄ and M₅ is connected to terminal T_{PROT}, and the body (or back-gate) of each of M₃, M₄ and M₅ is connected to a reference (REF) terminal (which in this case is connected to ground).

As described above with reference to FIG. 3, FETs M₁ and M₂ are arranged in a current mirror configuration and may be a matched pair (e.g., 1:1 ratio, with respect to transistor width and length) and have a similar voltage threshold (V_{TH} sometimes called V_{GS}), although they need not be so matched. With their back-gates connected to the REF terminal, the threshold voltages V_{TH} of each of FET M₃, M₄ and M₅ are larger than the V_{TH} of M₁. In one example, for instance, R₃, R₄, R₅ and R₆ are each in the range of 10 KOhms to 200 KOhms (e.g., each of R₃, R₄, R₅ and R₆ is in the range of about 10 KOhms to 100 KOhms), the threshold voltage V_{TH} of each of FETs M₃, M₄, and M₅ is in the range of 2 to 5 volts, and the V_{TH} of each of M₁, and M₂ is in the range of 0.6 to 1 volt. The source-to-drain on-resistance (R_{SD_ON}) of each of N₃, M₄, and M₅ decreases proportionally with decreasing voltage at terminal T_{PROT}. In this manner, each of FETs M₃, M₄ and M₅ acts like a variable resistor and together they are configured to adaptively reduce the portion of the drive potential V_{DRV} applied at the M₁ gate, in a similar fashion as described above with reference to FET M₃ of FIG. 3.

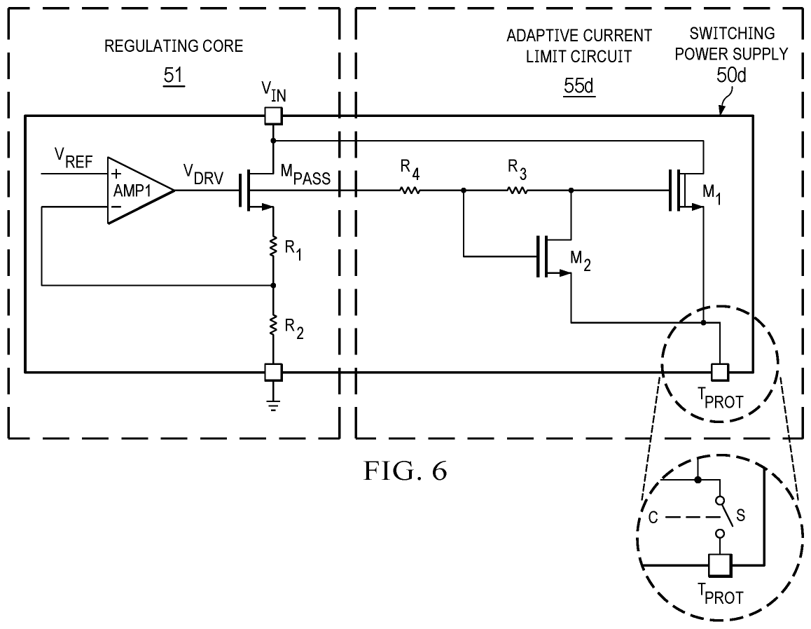

FIG. 6 illustrates a schematic diagram of a switching power supply 50d configured with an adaptive current limit circuit, in another example. As shown, switching power supply 50d generally includes a regulating core 51 and an adaptive current limit circuit 55d. Other portions of switching power supply 50d, such as the switching core, are not shown in FIG. 6, but are shown in FIGS. 7A-B. The regulating core 51 is configured as a voltage follower in a similar fashion to that shown in FIG. 2, and the above relevant description is equally applicable here.

The adaptive current limit circuit 55d also includes n-channel depletion or low threshold voltage FET M₁, which is configured as a source follower power supply, so as to source power from the input voltage terminal V_{IN} to terminal T_{PROT}, responsive to the output voltage V_{DRV} of amplifier AMP1. However, the percentage or proportion of the output voltage V_{DRV} of amplifier AMP1 that is applied to the gate of FET M₁ can be varied based on the voltage level at terminal T_{PROT}. For instance, example circuit 55d further includes resistors R₃ and R₄ operatively coupled to n-channel FET M₂, which is connected in a serial fashion between the M₁ gate and terminal T_{PROT}. In more detail, resistors R₃ and R₄ are connected in series with one another between the AMP1 output and the M₁ gate, and can be used to fine tune the current flowing through M₁. The M₂ drain is connected to the M₁ gate, and resistor R₃ is connected between the gate and drain of M₂. The M₂ source is connected to terminal T_{PROT}.

FETs M₁ and M₂ are different in size, with M₁ being much larger than M₂ (e.g., 1000:1 ratio, or larger, with respect to transistor width and length). Also, the threshold voltage V_{TH} of M₂ is greater than the V_{TH} of M₁. In some examples: if M₁ is a depletion FET its V_{TH} may be in the range of −0.1 to −0.2 volts, and if M₁ is a low threshold FET its V_{TH} may be in the range of 0.1 to 0.2 volts; V_{TH} of M₁ is in the range of 0.6 to 1 volt; R₃ is in the range of about 1 KOhm to 10 KOhms; and R is in the range of about 100 KOhms to 200 KOhms. The source-to-drain on-resistance (R_{SD-ON}) of M₂ decreases proportionally with decreasing voltage at terminal T_{PROT}. In this manner, FET M₂ acts like a variable resistor and is configured to adaptively reduce the portion of the drive potential V_{DRV} applied at the M₁ gate, by M₂ turning on responsive to a voltage at the terminal T_{PROT} being lower than it should be (lower than a voltage level). The lower the voltage at terminal T_{PROT}, the lower the R_{SD} of M₂ (the more M₂ turns on). The lower the R_{SD} of M₂, the lower the portion of V_{DRV} applied to the M₁ gate.

For example, assume that terminal T_{PROT} is a boot capacitor terminal for a boot strap circuit of switching power supply 50d, and the voltage at terminal T_{PROT} is V_{BOOT} (e.g., about 5 volts) under normal conditions. Further assume V_{DRV} is around 5 volts, and that V_{TH} of M₂ is about 0.6 volts. So, in a normal operation mode, V_{DRV}−V_{BOOT} is less than V_{TH} of M₂ (e.g., 5 volts −5 volts=0 volts, which is less than 0.6 volts) and M₂ is off or otherwise barely conducting and is thus effectively an open circuit (e.g., R_{SD_ON} of M₂≥1 MOhm to infinite, or otherwise very high resistance). As such, the M₁ gate receives about 100% of V_{DRV}.

However, responsive to V_{DRV}−V_{DRV} meeting or exceeding V_{TH} of M₂, normal operation mode ceases and M₂ begins to conduct and the R_{SD_ON} of M₂ is set proportional to V_{DRV}−V_{BOOT}. So, as the value of V_{DRV}−V_{BOOT} further increases past V_{TH} of M₂, the more M₂ is turns on (the current conducted through M₂ increases with increasing values of V_{DRV}−V_{BOOT}). If terminal T_{PROT} is shorted to ground, then V_{DRV}−V_{BOOT} is the maximum amount it can be and R_{SD_ON} of M₂ is the lowest it can be (e.g., <1 Ohm or otherwise very small relative to the impedance at the M₁ gate). With M₂ conducting, a variable voltage divider is formed which allows the amount of V_{DRV} applied to the M₁ gate to be varied proportionally, relative to the voltage at terminal T_{PROT}. For instance, with terminal T_{PROT} shorted to ground, current sourced from the V_{DRV} potential seeks the lower resistant path through M₂ (relative to the high impedance path to the M₁ gate), and the M₁ gate thus receives about 0% or an otherwise relatively small amount of V_{DRV}. For non-zero (non-short) voltage values at terminal T_{PROT}, the M₁ gate may receive a proportional amount of V_{DRV} (some value between about 0 volts and the full V_{DRV} potential). Thus, an adaptive limit on V_{IN} supply current through M₁ is provided.

As further shown in FIG. 6 in the dashed circle, some examples of switching power supply 50d may include a switch S coupled between the terminal T_{PROT} and the sources of M₁ and M₂ in a fashion similar to that shown in the examples of FIGS. 3-5, and the above relevant description is equally applicable here.

FIG. 7A illustrates a further detailed schematic diagram of a switching power supply 50e configured with an adaptive current limit circuit, in another example. As shown, switching power supply 50e generally includes a regulating core 51, a switching core 53, and an adaptive current limit circuit 55e. The regulating core 51 is configured as a voltage follower in a similar fashion to that shown in FIG. 2, and the above relevant description is equally applicable here.

The switching core 53 of this example is configured as a buck converter with low-side and high-side switching elements and corresponding driver circuits. In more detail, high-side switching element M_{L} is coupled between the input voltage terminal V_{IN} and the switching node SN, and has its control terminal coupled to the output of high-side driver HSD. The low-side switching element M₁ is coupled between the ground terminal and the switching node SN, and has its control terminal coupled to the output of low-side driver LSD. A pulse width modulator (PWM) controller 703 receives as input a reference voltage V_{REF2} and a feedback voltage V_{FB} representative of the output voltage V_{OUT}, and generates the high-side and low-side drive signals HS_{DRV} and LS_{DRV} which are provided to the high-side driver HSD input and the low-side driver LSD input, respectively. V_{REF2} may be provided, for example, by a bandgap voltage reference, and feedback voltage V_{FB} is generated by a voltage divider including resistors R₇ and R₈ serially-connected between the V_{OUT} and ground terminals. Switching elements M_{H} and M_{L} are both implemented with an n-channel power FET, although any number of other transistor technologies can be used. The PWM controller 703 can be implemented with any suitable PWM control scheme and circuitry.

As further shown, the positive supply terminal of the high-side driver HSD is coupled to the boot node and terminal T_{PROT} and the negative supply terminal of the high-side driver HSD is coupled to the switching node SN. Also, a boot capacitor is coupled between the terminal T_{PROT} and the switching node SN. The positive supply rail is provided by the adaptive current limit circuit 55e, which is configured as shown in FIG. 3 and the relevant above description is equally applicable here. As such, in the event of a short-circuit or high-current condition at terminal T_{PROT}, the current through M₁ will be adaptively limited as described herein. As further shown, the positive supply terminal of the lower-side driver LSD is coupled to the VCC node or terminal and the negative supply terminal of the low-side driver LSD is coupled to ground. In some examples, the positive supply rail VCC may be provided by a second occurrence of adaptive current limit circuit 55e. As such, in the event of a short-circuit or high-current condition at the VCC node, the sourced current can be adaptively limited as described herein. In some such cases, the V signal generated by the regulating core 51 can be applied (shared) to each copy of the adaptive current limit circuit 55e.

As further shown, an inductor L is coupled between the switching node SN and the output voltage terminal, and an output capacitor C_{OUT} is coupled between the V_{OUT} and ground terminals. Any number of loads may be connected between the V_{OUT} and ground terminals, for a given power supply application.

FIG. 7B illustrates a further detailed schematic diagram of a switching power supply 50f configured with an adaptive current limit circuit, in another example. As shown, switching power supply 50f generally includes a regulating core 51, a switching core 53, and an adaptive current limit circuit 55f. Each of the regulating core 51 and switching core 53 is configured in a similar fashion to that shown in FIGS. 3 and 7A, and the above relevant description is equally applicable here. In this example, the positive supply rail of the high-side driver HSD is provided by the adaptive current limit circuit 55f, which is configured as shown in FIG. 6 and the relevant above description is equally applicable here. As such, in the event of a short-circuit or high-current condition at terminal T_{PROT}, the current through M₁ will be adaptively limited as described herein. As further shown, the positive supply terminal of the lower-side driver LSD is coupled to the VCC node or terminal and the negative supply terminal of the low-side driver LSD is coupled to ground. In some examples, the positive supply rail VCC may be provided by a second occurrence of adaptive current limit circuit 55f, so that current sourced to the VCC terminal can also be adaptively limited as described herein. In a fashion similar to that described with respect to FIG. 7A, V_{DRV} generated by the regulating core 51 can be shared by both copies of the adaptive current limit circuit 55f.

Other examples may include additional circuitry not shown in FIGS. 7A-B. For example, regulating core 51 may further include bandgap voltage reference circuitry configured generate voltage reference V_{REF1} and V_{REF2}, a current bias generator to generate a current bias for biasing inputs or nodes per a given design, an error amplifier for comparing voltage values, logic circuitry for controlling operation, current sensing circuitry, and other such functional blocks.

FIG. 8A illustrates a schematic diagram of an LDO voltage regulator 100a configured with an adaptive current limit circuit, in an example. As shown, the LDO voltage regulator 100a includes a V2I circuit 102, a V_{REF} circuit 104, a dropout detection circuit 106, and an LDO core 108a. The adaptive current limit circuit 110a is implemented within the LDO core 108a. The LDO voltage regulator 100a receives input voltage V_{IN} at its input voltage terminal, and provides output voltage V_{OUT} at its output voltage terminal. Each of the V2I circuit 102, a V_{REF} circuit 104, a dropout detection circuit 106, and an LDO core 108a can be configured in a similar fashion to that described with reference to FIG. 1B, with further details of adaptive current limit circuit 110a provided with respect to FIG. 3, and the above relevant description is equally applicable here.

As further shown in FIG. 8A, V circuit 104 is configured to generate a reference voltage V_{REF} for LDO core 108a, based on bias current I_{BIAS} from V2I circuit 102. In this example, V_{REF} circuit 104 includes an amplifier AMP2 and p-channel FET M₄. FET M₄ is gated or otherwise controlled by the output signal V_{G} of AMP2. AMP2 is configured with input resistors R_{P} and R_{N} on its non-inverting and inverting inputs, respectively, and operates in conjunction with bias current I_{BIAS} to determine reference current I_{REF}. I_{REF} is passed through FET M₄ and a reference resistor R_{EXT} (which is external to the V_{REF} circuit 104 in this example), which in turn generates the reference voltage V_{REF} that is provided to LDO core 108a.

As further shown in FIG. 8A, the LDO core 108a is configured to provide V_{OUT} based on V_{IN} and V_{REF}. In this example, the LDO core 108a includes amplifier AMP1 configured to generate V_{DRV}, based on VREF (applied to non-inverting input of AMP1) and a feedback voltage taken at terminal T_{PROT} (applied to inverting input of AMP1). The output of AMP1 is applied to the adaptive current limit circuit 110a. In this example, the current limit circuit 110a includes resistors R₁ and R₂ operatively coupled to n-channel FETs M₂ and FET M₃, which are connected in a serial fashion between the gate of FET M₁ and terminal T_{PROT}. In more detail, resistors R₁ and R₂ are connected in series with one another between the AMP1 output and the M₁ gate, and can be used to fine tune the current flowing through M₁. The M₂ drain is connected to the M₁ gate, and resistor R₂ is connected between the gate and drain of M₂. The M₃ drain is connected to the M₂ source, and resistor R₂ is connected between the AMP1 output and the gates of M₂ and M₃. The M₃ source is connected to terminal T_{PROT} (which in this example is also V_{OUT}), and the M₃ body (or back-gate) is connected to ground. An output capacitor C_{OUT} is coupled between V_{OUT} and ground terminals.

As further shown in FIG. 8A, FETs M₁ and M₂ are arranged in a current mirror configuration and may be a matched pair (e.g., 1:1 ratio, with respect to transistor width and length) and have a similar voltage threshold V_{TH}, although they need not be so matched. With its back-gate connected to ground, the threshold voltage V of FET M₃ is larger than the V_{TH} of M₁. In one example, for instance, R₁ and R₂ are each in the range of 10 KOhms to 200 KOhms (e.g., R is in the range of about 100 KOhms to 200 KOhms; R₂ is in the range of about 10 KOhms to 100 KOhms), V_{TH} of FET M₃ is in the range of 2 to 5 volts, and V_{TH} of each of M₁ and M₂ is in the range of 0.6 to 1 volt. In operation, R_{SD_ON} of M₃ decreases proportionally with decreasing voltage at terminal T_{PROT}. In this manner, M₃ effectively acts like a variable resistor and adaptively reduces the portion of V_{DRV} applied at the M₁ gate, by M₂ turning on responsive to voltage at the terminal T_{PROT} being lower than it should be (thus indicating a high-current condition, such as a short-circuit). The lower the voltage at terminal T_{PROT}, the lower the R_{SD_ON} of M₃ (and the more M₃ turns on). The lower the R_{SD-ON} of M₃, the lower the portion of V_{DRV} applied to the M₁ gate, as described above with respect to FIG. 1B. Thus, current through M₁ is adaptively limited by the adaptive voltage divider provided by the operation of M₃, responsive to unusually low voltage at terminal T_{PROT}.

FIG. 8B illustrates a schematic diagram of an LDO voltage regulator 100b configured with an adaptive current limit circuit, in another example. As shown, the LDO voltage regulator 100b is similar to LDO voltage regulator 100a of FIG. 8A, except that it includes an LDO core 108b implemented with an adaptive current limit circuit 110b. Adaptive current limit circuit 110b is configured in a similar fashion to adaptive current limit circuit 55d described with respect to FIG. 6. The above relevant description is equally applicable here.

As shown in FIG. 8B, resistors R₁ and R₂ are connected in series with one another between the AMP1 output and the M₁ gate, and can be used to fine tune the current flowing through M₁. The M₂ drain is connected to the M₁ gate, and resistor R₂ is connected between the gate and drain of M₂. The M₂ source is connected to terminal T_{PROT} (which in this example is also V_{OUT}). FETs M₁ and M₂ are different in size, with M₁ being much larger than M₂ (e.g., 1000:1 ratio, or larger, with respect to transistor width and length). Also, V_{TH} of M₂ is greater than V_{TH} of M₁. In some examples: if M₁ is a depletion FET its V may be in the range of −0.1 to −0.2 volts, and if M₁ is a low threshold FET its V_{TH} may be in the range of 0.1 to 0.2 volts; V_{TH} of M₂ is in the range of 0.6 to 1 volt; R₁ is in the range of about 100 KOhms to 200 KOhms; and R₂ is in the range of about 1 KOhm to 10 KOhms. R_{SD_ON} of M₂ decreases proportionally with decreasing voltage at terminal T_{PROT}. In this manner, M₂ acts like a variable resistor and adaptively reduces the portion of V_{DRV} applied at the M₁ gate, by M₂ turning on responsive to a voltage at the terminal T_{PROT} being lower than it should be. The lower the voltage at terminal T_{PROT}, the lower the R_{SD_ON} of M₂ (the more M₂ turns on). The lower the R_{SD_ON} of M₂, the lower the portion of V_{DRV} applied to the M₁ gate.

So, in this particular example, terminal T_{PROT} is the V_{OUT} terminal of LDO voltage regulator 100b. Assume the voltage at terminal T_{PROT} is supposed to be about 5 volts under normal conditions. Further assume V_{DRV} is around 5 volts, and that V_{TH} of M₂ is about 0.6 volts. So, in a normal operation mode, V₁−V_{BOOT} is less than V_{TH} of M_{TH} (e.g., 5 volts−5 volts=0 volts, which is less than 0.6 volts) and M₂ is off or otherwise barely conducting and is thus effectively an open circuit (e.g., R_{SD_ON} of M₂≥1 MOhm to infinite, or otherwise very high resistance). As such, the M₁ gate receives about 100% of V.

However, responsive to V_{DRV}−V_{BOOT} meeting or exceeding V_{TH} of M₂, normal operation mode ceases and M₂ begins to conduct and the R_{SD_ON} of M₂ is set proportional to V_{DRV}−V_{BOOT}. So, as the value of V_{DRV}−V_{BOOT} further increases past V_{TH} of M₂, the more M₂ is turns on (the current conducted through M₂ increases with increasing values of V_{DRV}−V_{1 BOOT}). If terminal T_{PROT} is shorted to ground, then V_{DRV}−V_{BOOT} is the maximum amount it can be and R_{SD_ON} of M₂ is the lowest it can be (e.g., <1 Ohm or otherwise very small relative to the impedance at the M₂ gate). With M₂ conducting, a variable voltage divider is formed which allows the amount of V_{DRV} applied to the M₁ gate to be varied proportionally, relative to the voltage at terminal T_{PROT}. For instance, with terminal T_{PROT} shorted to ground, current sourced from the V_{DRV} potential seeks the lower resistant path through M₂ (relative to the high impedance path to the M₁ gate), and the M₁ gate thus receives about 0% or an otherwise relatively small amount of V_{DRV}. For non-zero (non-short) voltage values at terminal T_{PROT}, the M₁ gate may receive a proportional amount of V_{DRV} (some value between about 0 volts and the full V_{DRV} potential). Thus, an adaptive limit on V_{IN} supply current through M₁ is provided.

### Methodology

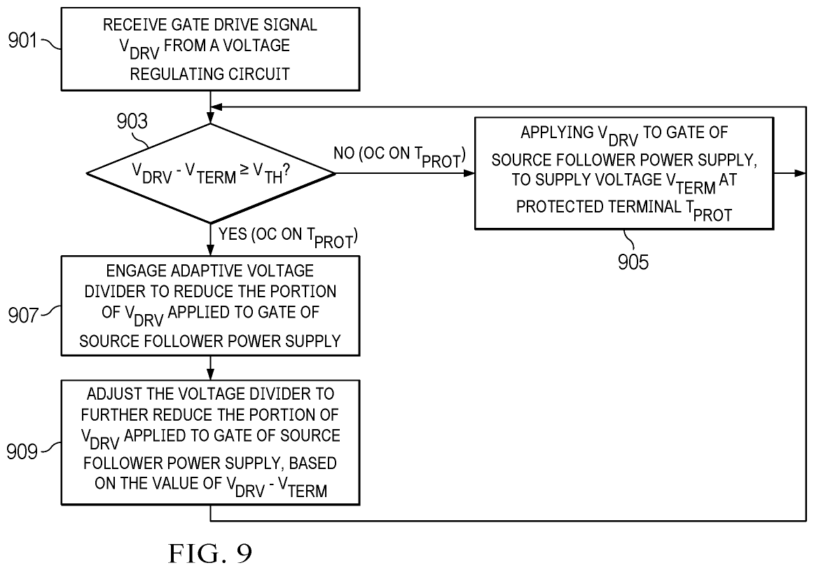

FIG. 9 illustrates a method for adaptively limiting current in a regulated power supply, in an example. The method can be carried out in any number of power supply topologies and configurations, such as the examples shown in FIGS. 1A-8B, or any other power supply having a terminal (T_{PROT}) to which a voltage (V_{TERM}) is sourced via a source follower power supply. In this example methodology, assume a first transistor configured as a source follower voltage supply has a first V_{TH} and is coupled between a power supply rail and T_{PROT}, and a second transistor having a second V_{TH} greater than the first V_{TH} is coupled between the gate of the first transistor and T_{PROT}. Also, the control terminals of the first and second transistors each receives some portion of drive signal (e.g., 0% to 100% of V_{DRV}). For purposes of this example description, assume the first and second transistors are FETs, such as M₁ and M₃ of the example circuits depicted in FIGS. 3-5, 7A, or 8A, or M₁ and M₂ of the example circuits depicted in FIG. 6, 7B, or 8B.

At 901 and 903, respectively, the method includes receiving a gate drive signal V_{DRV} from a voltage regulating circuit, and determining whether the difference between V_{DRV} and V_{TERM} (V_{DRV}−V_{TERM}) is greater than or equal to V_{TH} of the second transistor. The voltage regulating circuit may be, for example, regulating core 51 of any of switching power supplies 50a-f, or amplifier AMP1 of LDO voltage regulators 100a-b. More generally, V_{DRV} can be provided by any circuit configured to generate a drive signal for a power supply switching element. In this example, the determination at 903 is made by operation of the second transistor. This determination is indicative of whether there is an over-current (OC) condition on T_{PROT}.

Responsive to the difference of V_{DRV}−V_{TERM} not being greater than or equal to V_{TH} of the second transistor, the second transistor remains in its off or non-conducting state and the method continues at 905 with applying all (or substantially all, such as 90% or more) of V_{DRV} to the gate of the first transistor, to supply voltage V_{TERM} at protected terminal T_{PROT}. Such a determination and corresponding action may be indicative of a normal operation mode, where there is no over-current condition on the terminal T_{PROT}.

In contrast, responsive to the difference of V_{DRV}−V_{TERM} being greater than or equal to V_{TH} of the second transistor, the second transistor turns on or otherwise begins to conduct and the method continues at 907 and 909, respectively, with engaging an adaptive voltage divider to reduce the portion of V_{DRV} applied to the gate of the first transistor, and adjusting the voltage divider to further reduce the portion of V_{DRV} applied to gate of the first transistor (source follower power supply), based on the value of V_{DRV}−V_{TERM}. Such a determination and corresponding action may be indicative of an abnormal operation mode, where there is an over-current condition on the terminal T_{PROT}.

In this example, the adaptive voltage divider is effectively provided by operation of the second transistor having an R_{SD_ON} value that decreases proportionally with decreasing V_{TERM} values. In this manner, the second transistor effectively acts like a variable resistor. The lower the value of V_{TERM} at terminal T_{PROT}, the lower the R_{SD_ON} value of the second transistor (and the more the second transistor turns on). The lower the R_{SD_ON} value of the second transistor, the lower the portion of V_{DRV} applied to the gate of the first transistor. Thus, current through the first transistor is adaptively limited by the adaptive voltage divider provided by the operation of the second transistor, responsive to unusually low values of V_{TERM} at terminal T_{PROT}.

### Further Examples

Example 1 is a power supply circuit, comprising: an amplifier having an amplifier output, the amplifier configured to provide a drive potential at the amplifier output; a first transistor coupled between a voltage supply terminal and an output terminal, the first transistor having a first control terminal coupled to the amplifier output, and the first transistor configured to receive at least a portion of the drive potential at the first control terminal; and a second transistor coupled between the first control terminal and the output terminal, the second transistor having a second control terminal coupled to the amplifier output. A threshold voltage of the first transistor is lower than a threshold voltage of the second transistor, and the second transistor is configured to adaptively reduce the portion of the drive potential at the first control terminal by the second transistor turning on responsive to a voltage at the output terminal being lower than a voltage level. The degree to which the second transistor turns on may vary based on the magnitude of the voltage at the output terminal.

Example 2 includes the power supply circuit of Example 1, and further includes one or more resistors coupled between the first control terminal of the first transistor and the second control terminal of the second transistor.

Example 3 includes the power supply circuit of Example 1 or 2, wherein the output terminal is a boot capacitor terminal or an output voltage terminal.

Example 4 includes the power supply circuit of any one of Examples 1 through 3, wherein the amplifier is configured as a unity follower.

Example 5 includes the power supply circuit of any one of Examples 1 through 4, and further includes a switch coupled between the first transistor and the output terminal.

Example 6 includes the power supply circuit of any one of Examples 1 through 5, wherein the second transistor is configured to adaptively reduce the portion of the drive potential at the first control terminal by adaptively changing channel resistance of the second transistor, based on a potential difference between the drive potential and the voltage at the output terminal.

Example 7 includes the power supply circuit of any one of Examples 1 through 6, wherein: the first and second transistors are field effect transistors (FETs); the first transistor is a depletion mode or native transistor having its drain coupled to the voltage supply terminal and its source coupled to the output terminal, and its gate is the first control terminal; and the second transistor is smaller than the first transistor and has its drain coupled to the gate of the first transistor and its source coupled to the output terminal, and its gate is the second control terminal.

Example 8 includes the power supply circuit of any one of Examples 1 through 6, wherein: the first and second transistors are field effect transistors (FET); the first transistor having its drain coupled to the voltage supply terminal and its source coupled to the output terminal, and its gate is the first control terminal; and the second transistor has its source coupled to the output terminal, its body terminal coupled to a reference terminal, and its gate is the second control terminal.

Example 9 includes the power supply circuit of any one of Examples 1 through 8, wherein the power supply circuit is a buck converter circuit or a low dropout (LDO) voltage regulator circuit.

Example 10 is an integrated circuit package comprising the power supply circuit of any one of Examples 1 through 9, wherein the output terminal is a pin or pad of the integrated circuit package.

Example 11 is a power supply circuit, comprising: an amplifier having an amplifier output and a voltage reference input; a first transistor coupled between a voltage supply terminal and an output terminal, the first transistor having a first control terminal coupled to the amplifier output; a second transistor coupled between the first transistor and the output terminal, the second transistor having a second control terminal coupled to the amplifier output; and a third transistor coupled between the second transistor and the output terminal, the third transistor having a third control terminal and a body terminal, the third control terminal coupled to the amplifier output, and the body terminal coupled to a reference terminal.

Example 12 includes the power supply circuit of Example 11, and further includes a first resistor coupled between the first control terminal of the first transistor and the second control terminal of the second transistor; and/or a second resistor coupled between the second control terminal of the second transistor and the third control terminal of the third transistor.

Example 13 includes the power supply circuit of Example 11 or 12, wherein the output terminal is a boot capacitor terminal and the reference terminal is a ground terminal.

Example 14 includes the power supply circuit of any one of Examples 11 through 13, wherein the amplifier is configured as a unity follower.

Example 15 includes the power supply circuit of any one of Examples 11 through 14, and further includes: one or more fourth transistors coupled between the third transistor and the output terminal, each of the one or more fourth transistors having a respective control terminal coupled to the amplifier output and a respective body terminal coupled to the reference terminal;

and a resistor coupled between the third control terminal of the third transistor and the one or more control terminals of the one or more fourth transistors.

Example 16 includes the power supply circuit of any one of Examples 11 through 14, and further includes: one or more fourth transistors coupled in parallel with the third transistor, each of the one or more fourth transistors having a respective control terminal coupled to the amplifier output and a respective body terminal coupled to the reference terminal; and a resistor coupled between the third control terminal of the third transistor and the one or more control terminals of the one or more fourth transistors.

Example 17 includes the power supply circuit of any one of Examples 11 through 16, and further includes a switch coupled between the first transistor and the output terminal.

Example 18 includes the power supply circuit of any one of Examples 11 through 17, wherein: the first, second and third transistors are field effect transistors (FETs); the first transistor having its drain coupled to the voltage supply terminal and its source coupled to the output terminal, and its gate is the first control terminal coupled to the amplifier output; the second transistor having its drain coupled to the gate of the first transistor and its source coupled to the drain of the third transistor, and its gate is the second control terminal coupled to the amplifier output; and the third transistor has its source coupled to the output terminal, and its gate is the third control terminal coupled to the amplifier output, and its back gate is the body terminal coupled to the reference terminal.

Example 19 includes the power supply circuit of Example 18, wherein the first, second and third transistors are n-channel field effect transistors (NFETs), and the power supply circuit further comprises: a first resistor coupled between the gate of the first transistor and the gate of the second transistor; and a second resistor coupled between the gate of the second transistor and the gate of the third transistor.

Example 20 includes the power supply circuit of any one of Examples 11 through 19, wherein the power supply circuit is part of a buck converter circuit or a low dropout (LDO) voltage regulator circuit.

Example 21 is an integrated circuit package comprising the power supply circuit of any one of Examples 11 through 20, wherein the output terminal is a pin or pad of the integrated circuit package.

Example 22 is a power supply circuit, comprising: an amplifier having an amplifier output and a voltage reference input; a first transistor coupled between a voltage supply terminal and an output terminal, the first transistor having a first control terminal coupled to the amplifier output; and a second transistor coupled between the first control terminal and the output terminal, the second transistor having a second control terminal coupled to the amplifier output; wherein a threshold voltage of the first transistor is lower than a second threshold voltage of the second transistor.

Example 23 includes the power supply circuit of Example 22, and further includes: a first resistor coupled between the first control terminal of the first transistor and the second control terminal of the second transistor; and/or a second resistor coupled between the second control terminal of the second transistor and the amplifier output.

Example 24 includes the power supply circuit of Example 22 or 23, wherein the output terminal is a boot capacitor terminal or an output voltage terminal.

Example 25 includes the power supply circuit of any one of Examples 22 through 24, wherein the amplifier is configured as a unity follower.

Example 26 includes the power supply circuit of any one of Examples 22 through 25, and further includes a switch coupled between the first transistor and the output terminal.

Example 27 includes the power supply circuit of any one of Examples 22 through 24, wherein: the first and second transistors are field effect transistors (FETs); the first transistor is a depletion mode or native transistor having its drain coupled to the voltage supply terminal and its source coupled to the output terminal, and its gate is the first control terminal coupled to the amplifier output; and the second transistor is smaller than the first transistor and has its drain coupled to the gate of the first transistor and its source coupled to the output terminal, and its gate is the second control terminal coupled to the amplifier output.

Example 28 includes the power supply circuit of Example 27, wherein the first and second transistors are n-channel field effect transistors (NFETs), and a size ratio of the first transistor to the second transistor is 1000:1 or higher.

Example 29 includes the power supply circuit of any one of Examples 22 through 28, wherein the power supply circuit is part of a buck converter circuit or a low dropout (LDO) voltage regulator circuit.

Example 30 includes an integrated circuit package comprising the power supply circuit of any one of Examples 22 through 29, wherein the output terminal is a pin or pad of the integrated circuit package.

Example 31 is a method for adaptively limiting current in a regulated power supply, the regulated power supply having a terminal (T_{PROT}) to which a voltage (V_{TERM}) is sourced, the regulated power supply further including a first transistor and a second transistor, the first transistor having a first V_{TH} and coupled between a power supply rail and T_{PROT}, and the second transistor having a second V_{TH} greater than the first V_{TH} and coupled between the gate of the first transistor and T_{PROT}. The method includes: receiving a gate drive signal V_{DRV} from a voltage regulating circuit. Responsive to the difference of V_{DRV}−V_{TERM} not being greater than or equal to V_{TH} of the second transistor, the method includes applying substantially all of V_{DRV} to the gate of the first transistor. Responsive to the difference of V_{DRV}−V_{TERM} being greater than or equal to V_{TH} of the second transistor, the method includes: engaging an adaptive voltage divider to reduce the portion of V_{DRV} applied to the gate of the first transistor, and adjusting the voltage divider to further reduce the portion of V_{DRV} applied to gate of the first transistor, based on the value of V_{DRV}−V_{TERM}.

Example 32 includes the method of Example 31, wherein the lower the value of V_{TERM} at terminal T_{PROT}, the more the second transistor turns on.

Example 33 includes the method of Example 32 or 33, wherein: the lower the value of V_{TERM} at terminal T_{PROT}, the lower an R_{SD_ON} value of the second transistor; and the lower the R_{SD_ON} value of the second transistor, the lower the portion of V_{DRV} applied to the gate of the first transistor.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end user and/or a third party.

While the use of particular transistors is described herein, other transistors (or equivalent devices) may be used instead. For example, a p-channel field effect transistor (PFET) may be used in place of an n-channel field effect transistor (NFET) with little or no changes to the circuit. Furthermore, other types of transistors may be used (such as bipolar junction transistors (BJTs)). Furthermore, the devices may be implemented in/over a silicon substrate (Si), a silicon carbide substrate (SiC), a gallium nitride substrate (GaN) or a gallium arsenide substrate (GaAs).

References herein to a field effect transistor (FET) being “ON” means that the conduction channel of the FET is present and drain current may flow through the FET. References herein to a FET being “OFF” means that the conduction channel is not present and drain current does not flow through the FET. A FET that is OFF, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

Modifications are possible in the described embodiments, and other embodiments are possible, within the scope of the claims.

What is claimed is:

1. A power supply circuit, comprising:
an amplifier having an amplifier output, the amplifier configured to provide a drive potential at the amplifier output;
a first transistor coupled between a voltage supply terminal and an output terminal, the first transistor having a first control terminal coupled to the amplifier output, and the first transistor configured to receive at least a portion of the drive potential at the first control terminal; and
a second transistor coupled between the first control terminal and the output terminal, the second transistor having a second control terminal coupled to the amplifier output;
wherein a threshold voltage of the first transistor is lower than a threshold voltage of the second transistor, and the second transistor is configured to adaptively reduce the portion of the drive potential at the first control terminal by the second transistor turning on responsive to a voltage at the output terminal being lower than a voltage level.

2. The power supply circuit of claim 1, further comprising:
one or more resistors coupled between the first control terminal of the first transistor and the second control terminal of the second transistor.

3. The power supply circuit of claim 1, wherein the output terminal is a boot capacitor terminal or an output voltage terminal.

4. The power supply circuit of claim 1, wherein the amplifier is configured as a unity follower.

5. The power supply circuit of claim 1, further comprising a switch coupled between the first transistor and the output terminal.

6. The power supply circuit of claim 1, wherein the second transistor is configured to adaptively reduce the portion of the drive potential at the first control terminal by adaptively changing channel resistance of the second transistor, based on a potential difference between the drive potential and the voltage at the output terminal.

7. The power supply circuit of claim 1, wherein:
the first and second transistors are field effect transistors (FETs);
the first transistor is a depletion mode or native transistor having its drain coupled to the voltage supply terminal and its source coupled to the output terminal, and its gate is the first control terminal; and
the second transistor is smaller than the first transistor and has its drain coupled to the gate of the first transistor and its source coupled to the output terminal, and its gate is the second control terminal.

8. The power supply circuit of claim 1, wherein:
the first and second transistors are field effect transistors (FET);
the first transistor having its drain coupled to the voltage supply terminal and its source coupled to the output terminal, and its gate is the first control terminal; and
the second transistor has its source coupled to the output terminal, its body terminal coupled to a reference terminal, and its gate is the second control terminal.

9. The power supply circuit of claim 1, wherein the power supply circuit is a buck converter circuit or a low dropout (LDO) voltage regulator circuit.

10. An integrated circuit package comprising the power supply circuit of claim 1, wherein the output terminal is a pin or pad of the integrated circuit package.

11. A power supply circuit, comprising:
an amplifier having an amplifier output and a voltage reference input;
a first transistor coupled between a voltage supply terminal and an output terminal, the first transistor having a first control terminal coupled to the amplifier output;
a second transistor coupled between the first transistor and the output terminal, the second transistor having a second control terminal coupled to the amplifier output; and
a third transistor coupled between the second transistor and the output terminal, the third transistor having a third control terminal and a body terminal, the third control terminal coupled to the amplifier output, and the body terminal coupled to a reference terminal.

12. The power supply circuit of claim 11, comprising:
a first resistor coupled between the first control terminal of the first transistor and the second control terminal of the second transistor; and/or
a second resistor coupled between the second control terminal of the second transistor and the third control terminal of the third transistor.

13. The power supply circuit of claim 11, wherein the output terminal is a boot capacitor terminal and the reference terminal is a ground terminal.

14. The power supply circuit of claim 11, further comprising:
one or more fourth transistors coupled between the third transistor and the output terminal, each of the one or more fourth transistors having a respective control terminal coupled to the amplifier output and a respective body terminal coupled to the reference terminal; and
a resistor coupled between the third control terminal of the third transistor and the one or more control terminals of the one or more fourth transistors.

15. The power supply circuit of claim 11, further comprising;
one or more fourth transistors coupled in parallel with the third transistor, each of the one or more fourth transistors having a respective control terminal coupled to the amplifier output and a respective body terminal coupled to the reference terminal; and
a resistor coupled between the third control terminal of the third transistor and the one or more control terminals of the one or more fourth transistors.

16. The power supply circuit of claim 11, wherein:
the first, second and third transistors are field effect transistors (FETs);
the first transistor having its drain coupled to the voltage supply terminal and its source coupled to the output terminal, and its gate is the first control terminal coupled to the amplifier output;
the second transistor having its drain coupled to the gate of the first transistor and its source coupled to the drain of the third transistor, and its gate is the second control terminal coupled to the amplifier output; and
the third transistor has its source coupled to the output terminal, and its gate is the third control terminal coupled to the amplifier output, and its back gate is the body terminal coupled to the reference terminal.

17. The power supply circuit of claim 16, wherein the first, second and third transistors are n-channel field effect transistors (NFETs), and the power supply circuit further comprises:
a first resistor coupled between the gate of the first transistor and the gate of the second transistor; and
a second resistor coupled between the gate of the second transistor and the gate of the third transistor.

18. A power supply circuit, comprising:
an amplifier having an amplifier output and a voltage reference input;
a first transistor coupled between a voltage supply terminal and an output terminal, the first transistor having a first control terminal coupled to the amplifier output; and
a second transistor coupled between the first control terminal and the output terminal, the second transistor having a second control terminal coupled to the amplifier output;
wherein a threshold voltage of the first transistor is lower than a second threshold voltage of the second transistor.

19. The power supply circuit of claim 18, comprising:
a first resistor coupled between the first control terminal of the first transistor and the second control terminal of the second transistor; and/or
a second resistor coupled between the second control terminal of the second transistor and the amplifier output.

20. The power supply circuit of claim 18, wherein the output terminal is a boot capacitor terminal or an output voltage terminal.

21. The power supply circuit of claim 18, wherein:
the first and second transistors are field effect transistors (FETs);
the first transistor is a depletion mode or native transistor having its drain coupled to the voltage supply terminal and its source coupled to the output terminal, and its gate is the first control terminal coupled to the amplifier output; and
the second transistor is smaller than the first transistor and has its drain coupled to the gate of the first transistor and its source coupled to the output terminal, and its gate is the second control terminal coupled to the amplifier output.

22. The power supply circuit of claim 21, wherein the first and second transistors are n-channel field effect transistors (NFETs), and a size ratio of the first transistor to the second transistor is 1000:1 or higher.
